(19) United States
(12) Patent Application Publication
(10) Pub. No.: US 2025/0228146 A1
(43) Pub. Date: Jul. 10, 2025

(54) SEMICONDUCTOR DEVICE, MEMORY STRUCTURE AND METHOD OF FORMING THE SAME

(71) Applicant: Taiwan Semiconductor Manufacturing Company, Ltd., Hsinchu (TW)

(72) Inventors: Hai-Dang Trinh, Hsinchu (TW); Fa-Shen JIANG, Taoyuan City (TW); Chung-Yi Yu, Hsin-Chu (TW); Cheng-Yuan Tsai, Hsin-Chu county (TW)

(73) Assignee: Taiwan Semiconductor Manufacturing Company, Ltd., Hsinchu (TW)

(21) Appl. No.: 18/408,487

(22) Filed: Jan. 9, 2024

(51) Int. Cl. H10N 70/00; H01L 23/522; H01L 23/528; H10B 63/00

(52) U.S. Cl. CPC H10N 70/841; H01L 23/5226; H01L 23/5283; H10B 63/30; H10N 70/061; H10N 70/8833

(57) ABSTRACT

A memory structure includes a bottom via, a memory cell and a top via. The memory cell is disposed on the bottom via and includes a bottom electrode, a top electrode and a first storage element layer and a second storage element layer sandwiched between the bottom electrode and the top electrode. The first storage element layer is in contact with the bottom electrode, and a crystallization temperature of the first storage element layer is higher than a crystallization temperature of the second storage element layer. The top via is disposed on the memory cell and electrically connected to the top electrode.

### BACKGROUND

Many modern day electronic devices include non-volatile memory. Non-volatile memory that is electronic memory that is able to store data in the absence of power. Some promising candidates for the next generation of non-volatile memory include resistive random-access memory (RRAM) and magnetoresistive random-access memory (MRAM). RRAM and MRAM have relatively simple structures, and are compatible with complementary metal-oxide-semiconductor (CMOS) logic fabrication processes.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the critical dimensions of the various features may be arbitrarily increased or reduced for clarity of discussion.

FIG. 1 to FIG. 6 are schematic sectional views of various stages in a method of forming a memory structure in accordance with some embodiments of the present disclosure.

FIG. 7 is a schematic sectional view of a memory structure during operation in accordance with some embodiments of the present disclosure.

FIG. 8 is a schematic sectional view of a memory structure during operation in accordance with some comparative embodiments of the present disclosure.

FIG. 9 is a schematic sectional view of a memory structure in accordance with some other embodiments of the present disclosure.

FIG. 10 is a schematic sectional view of a memory structure in accordance with some other embodiments of the present disclosure.

FIG. 11 is a schematic sectional view of a memory structure in accordance with some other embodiments of the present disclosure.

FIG. 12 is a schematic sectional view of a semiconductor device in accordance with some embodiments of the present disclosure.

FIG. 13 is a schematic sectional view of a semiconductor device in accordance with some other embodiments of the present disclosure.

FIG. 14 is a schematic sectional view of a semiconductor device in accordance with some other embodiments of the present disclosure.

FIG. 15 is a schematic sectional view of a semiconductor device in accordance with some other embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a second feature over or on a first feature in the description that follows may include embodiments in which the second and first features are formed in direct contact, and may also include embodiments in which additional features may be formed between the second and first features, such that the second and first features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath”, “below”, “lower”, “on”, “over”, “overlying”, “above”, “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments discussed herein may be discussed in a specific context, namely a method of forming a memory structure including forming memory cells having storage element layers. In resistive random-access memory (RRAM) memory cells, lower RRAM forming voltage is desirable for minimizing gate induced drain leakage, and to prevent transistor damage and circuit loading issue. A lower forming voltage may be achieved by reducing the thickness of the storage element layer (or switching layer). However, when the thickness of the storage element layer (or switching layer) is reduced, the RRAM memory cell may become unstable, and may easily degrade.

In accordance with some embodiments discussed herein, the stability of the RRAM memory cell is improved by using two storage element layers (or switching layers) having different crystallization temperatures. As such, when applying an appropriate voltage across the RRAM memory cell, the conductive filaments formed in the storage element layers are less likely to induce crystallization in the storage element layers. Overall, stability and reliability of the memory cell may be improved.

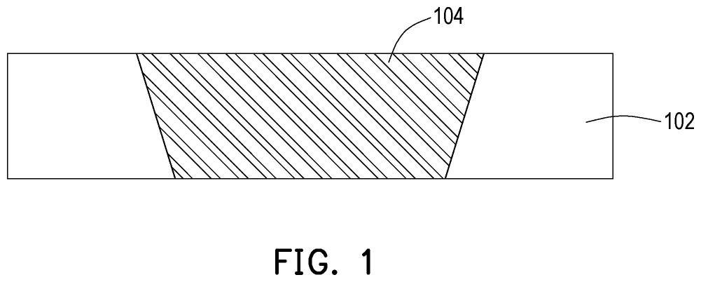

FIG. 1 to FIG. 6 are schematic sectional views of various stages in a method of forming a memory structure in accordance with some embodiments of the present disclosure. Referring to FIG. 1, a bottom via 104 is formed. For example, the bottom via 104 is embedded in a dielectric layer 102. In some embodiments, the dielectric layer 102 includes a dielectric material, such as silicon oxide, silicon nitride, silicon oxynitride, silicon carbonitride, silicon carbide oxynitride, spin-on glass (SOG), phosphosilicate glass (PSG), borophosphosilicate glass (BPSG), fluosilicate glass (FSG), carbon doped silicon oxide (e.g., SiCOH), polyimide, a spin-on dielectric material, a low-k dielectric material, or the like, and/or a combination thereof. It should be noted that the low-k dielectric materials are generally dielectric materials having a dielectric constant lower than 3.9. Examples of low-k dielectric materials include BLACK DIAMOND® (Applied Materials of Santa Clara, Calif.), Xerogel, Aerogel, amorphous fluorinated carbon, Parylene, BCB (bis-benzocyclobutenes), Flare, SILK® (Dow Chemical, Midland, Mich.), hydrogen silsesquioxane (HSQ) or fluorinated silicon oxide (SiOF), and/or a combination thereof.

In some embodiment, the dielectric layer 102 is formed by chemical vapor deposition (CVD) (e.g., flowable chemical vapor deposition (FCVD), plasma-enhanced chemical vapor deposition (PECVD), high density plasma CVD (HDPCVD) or sub-atmospheric CVD (SACVD)), molecular layer deposition (MLD), spin-on, sputtering, or other suitable methods. In one embodiment, the dielectric layer 102 is a one-layer structure. In some other embodiments, the dielectric layer 102 is a multi-layer structure. The disclosure is not limited thereto. In some embodiments, the dielectric layer 102 serves as an insulating layer, and may be referred as an inter-metal dielectric (IMD) layer.

As illustrated in FIG. 1, the bottom via 104 is formed in the dielectric layer 102 by a single damascene process. For example, an opening (not shown) is formed in the dielectric layer 102, and the opening is filled with a conductive material. Thereafter, a planarization process (e.g., a chemical-mechanical planarization (CMP) process) is performed to remove excessive conductive material, thereby forming the bottom via 104. In some embodiments, the surface of the bottom via 104 is exposed from a top surface of the dielectric layer 102. In certain embodiments, a top surface of the bottom via 104 is substantially coplanar with the top surface of the dielectric layer 102 after the planarization process.

In some embodiments, the bottom via 104 is electrically coupled to an overlying structure (e.g. coupled to a bottom electrode of a memory cell formed in subsequent steps). In certain embodiments, the bottom via 104 is configured to transmit the voltage applied to the bottom via 104 to a memory cell located thereon. The bottom via 104 may be a single-layer structure (of one material) or a multilayer structure (of two or more different structure), and may be formed using CVD, atomic layer deposition (ALD), physical vapor deposition (PVD), a combination thereof, or the like. A material of the bottom via 104, for example, includes aluminum (Al), Copper (Cu), tungsten (W), some other low resistance material, or a combination thereof. The bottom via 104 may have a round, square, rectangular, or other shaped profiles from a top view.

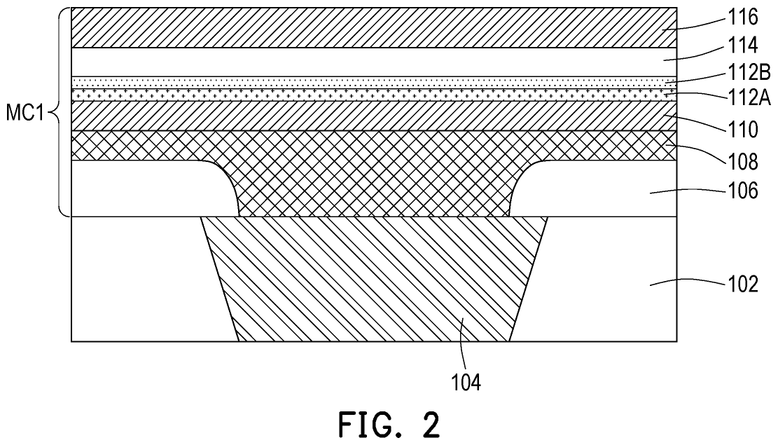

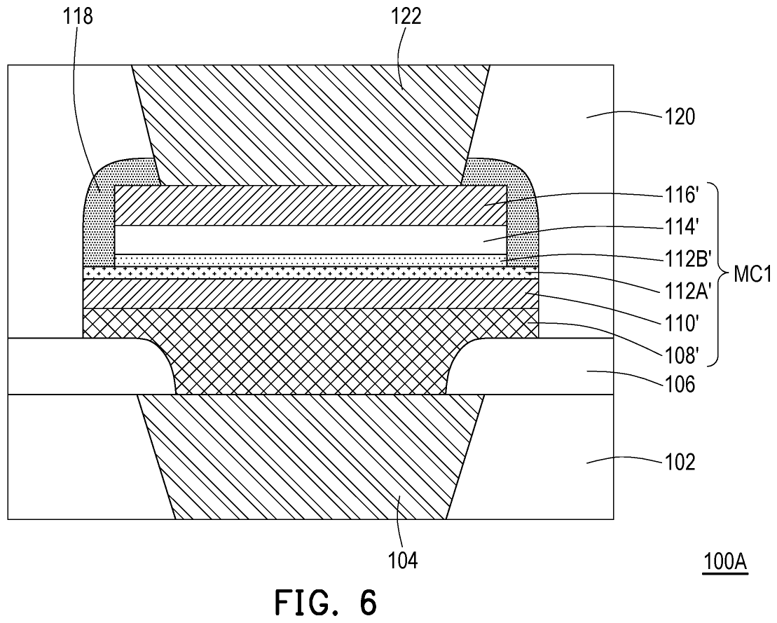

After forming the dielectric layer 102 and the bottom via 104, various steps of forming a memory cell MC1 and a top via 122 on the bottom via 104 (as shown in FIG. 6) will be described. Referring to FIG. 2, a dielectric layer 106 is formed on the dielectric layer 102. For example, the dielectric layer 106 may be formed of the same materials and made by the same methods as with the dielectric layer 102. Thus, the details of the dielectric layer 106 is omitted herein. In some embodiments, the dielectric layer 106 is patterned to form an opening revealing the bottom via 104. Thereafter, a barrier layer 108 is formed on the dielectric layer 106 and formed in the openings to contact the bottom via 104.

In some embodiments, the barrier layer 108 is formed of materials such as titanium (Ti), tantalum (Ta), titanium nitride (TiN), tantalum nitride (TaN), or other suitable material, and may be formed using CVD, ALD, PVD, a combination thereof, or the like. In some embodiments, the barrier layer 108 has a material different from that of the bottom via 104. For example, in one embodiment, the barrier layer 108 includes TaN while the bottom via 104 includes TiN.

After forming the barrier layer 108, a bottom electrode material 110, a first storage material 112A, a second storage material 112B, a capping layer material 114 and a top electrode material 116 are sequentially formed over the barrier layer 108 to form a memory material stack defining a memory cell MC1. In some embodiments, the bottom electrode material 110 is formed to physically contact the barrier layer 108, and include materials such as titanium (Ti), cobalt (Co), copper (Cu), ruthenium (Ru), iridium (Ir), aluminum copper (AlCu), tungsten (W), tungsten nitride (WN), titanium nitride (TiN), titanium tungsten (TiW), titanium aluminum (TiAl), titanium aluminum nitride (TiAlN), tantalum nitride (TaN), platinum (Pt), or a combination thereof. The bottom electrode material 110 may be formed by any suitable method, such as CVD, PVD, or the like. In certain embodiments, the bottom electrode material 110 has a thickness of about 20 nm to about 50 nm.

In some embodiments, the first storage material 112A is formed on the bottom electrode material 110 to contact the bottom electrode material 110, while the second storage material 112B is formed on the first storage material 112A to contact the first storage material 112A. The first storage material 112A and the second storage material 112B may be formed by any suitable method, such as PVD, ALD, or the like. In the exemplary embodiment, the first storage material 112A and the second storage material 112B are high K dielectric materials with a dielectric constant k greater than about 3.9, 5, 10, 15, or 20. Furthermore, in some embodiments, a crystallization temperature of the first storage material 112A is higher than a crystallization temperature of the second storage material 112B. For example, an average crystallization temperature of the first storage material 112A is greater than 500° C., greater than 600° C., or greater than 700° C. In one exemplary embodiment, the average crystallization temperature of the first storage material 112A may be in a range of 760° C. to 1200° C. In some embodiments, an average crystallization temperature the second storage material 112B is smaller than the first storage material 112A, and may be smaller than 700° C., smaller than 600° C., or smaller than 500° C.

In some embodiments, the first storage material 112A includes a combination of at least two materials. For example, in some embodiments, the first storage material 112A includes a first material having a bandgap of 5 eV or less, and includes at least one second material having a bandgap of 6 eV or more. In one exemplary embodiment, the first material is tantalum oxide (Ta₂O₅) with a bandgap of 4.2 eV, while the second material includes aluminum oxide (Al₂O₃) with a bandgap of 7.0 eV and/or tantalum oxide (Ta₂O₅) with a bandgap of 9.0 eV. In other words, the first storage material 112A includes a combination of tantalum oxide (Ta₂O₅) and aluminum oxide (Al₂O₃), includes a combination of tantalum oxide (Ta₂O₅) and silicon oxide (SiO₂), or includes a combination of tantalum oxide (Ta₂O₅), aluminum oxide (Al₂O₃) and silicon oxide (SiO₂).

In some embodiments, when the first storage material 112A includes the first material and the second material above, the first material and the second material are evenly distributed in the first storage material 112A to have a uniform atomic profile of elements from a bottom surface to a top surface of the first storage material 112A. In some other embodiments, when the first storage material 112A includes a combination of tantalum oxide (Ta₂O₅) and aluminum oxide (Al₂O₃), an atomic profile of aluminum is higher at a bottom surface (surface contacting bottom electrode material 110) of the first storage material 112A than at a top surface (surface contacting second storage material 112B) of the first storage material 112A. Furthermore, when the first storage material 112A includes a combination of tantalum oxide (Ta₂O₅) and silicon oxide (SiO₂), an atomic profile of silicon is higher at the bottom surface of the first storage material 112A than at the top surface of the first storage material 112A.

In some embodiments, the second storage material 112B includes a material different than that of the first storage material 112A. For example, in some embodiments, the second storage material 112B includes transition metal oxide materials, such as zirconium tantalum oxide (ZrTaO), hafnium tantalum oxide (HfTaO), hafnium aluminum oxide (HfAlO), hafnium oxide (HfO₂), and zirconium oxide (ZrO₂), or a combination thereof. In some embodiments, a sum of a thickness of the first storage material 112A and the second storage material 112B is in a range of 10 angstroms to 100 angstroms. For example, the first storage material 112A may have a thickness in a range of 5 angstroms to 50 angstroms, while the second storage material 112B may have a thickness in a range of 5 angstroms to 50 angstroms. In some embodiments, the thickness of the first storage material 112A is substantially equal to a thickness of the second storage material 112B. However, the disclosure is not limited thereto. In alternative embodiments, the thickness of the first storage material 112A may be smaller or greater than the second storage material 112B.

As further illustrated in FIG. 2, the capping layer material 114 is formed on the second storage material 112B and formed to be in contact with the second storage material 112B. The capping layer 114 is configured to store oxygen, which can facilitate resistance changes within the first storage material 112A and the second storage material 112B. For example, the capping layer material 114 may include materials such as hafnium (Hf), titanium (Ti), tantalum (Ta), aluminum (Al), zirconium (Zr), titanium nitride (TiN), tantalum nitride (TaN), and may be formed by any suitable method, such as PVD, ALD, or the like.

After forming the capping layer material 114, the top electrode material 116 is formed over the capping layer material 114. For example, the top electrode material 116 may include materials such as hafnium (Hf), titanium (Ti), tantalum (Ta), aluminum (Al), zirconium (Zr), titanium nitride (TiN), tantalum nitride (TaN), and may be formed by any suitable method, such as PVD, ALD, or the like. In some embodiments, the top electrode material 116 has a thickness of about 20 nm to about 50 nm. In certain embodiments, the top electrode material 116 may be formed of the same materials as the bottom electrode material 110, or may be formed of a different material than the bottom electrode material 110.

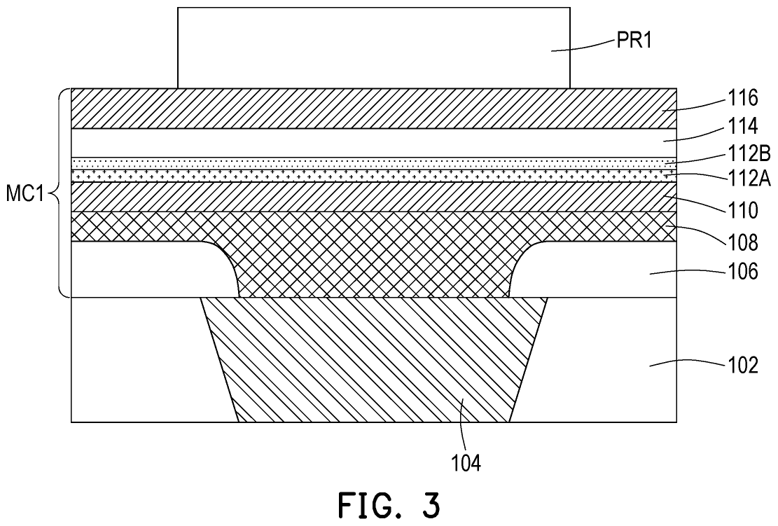

Referring to FIG. 3, in a subsequent step, a photoresist pattern PR1 or a masking pattern is formed on the top electrode material 116. The photoresist pattern PR1 may be located in an area corresponding to a center position of the top electrode material 116. Furthermore, the photoresist pattern PR1 may have a round, square, or rectangular profile in the top view, which may be adjusted based on design requirement. In one embodiment, the photoresist pattern PR1 may be formed by coating (such as spin-coating) and photolithography processes or the like; however, the disclosure is not limited thereto. A material of the photoresist pattern PR1, for example, includes a positive resist material or a negative resist material, that is suitable for a patterning process such as a photolithography process with a mask or a mask-less photolithography process (for instance, an electron-beam (e-beam) writing or an ion-beam writing). In the disclosure, the photoresist pattern PR1 is referred to as a photoresist layer or a resist layer.

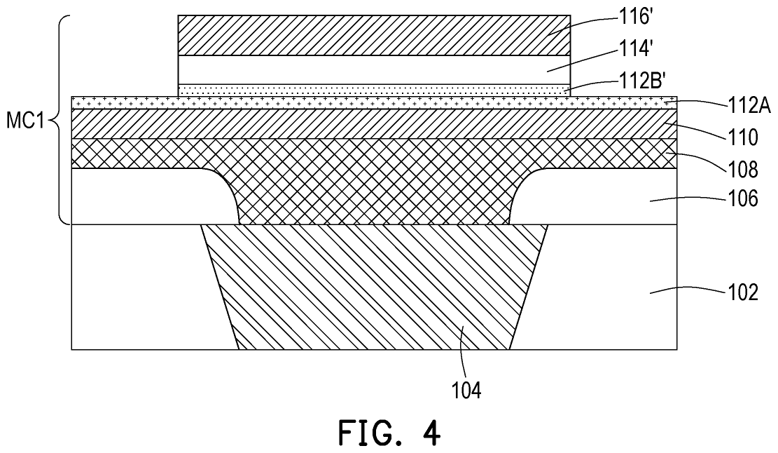

Referring to FIG. 4, in a subsequent step, a patterning process is performed to remove portions of the second storage material 112B, the capping layer material 114 and the top electrode material 116 to form a second storage element layer 112B′, a capping layer 114′ disposed on the second storage element layer 112B′, and a top electrode 116′ disposed on the capping layer 114′. For example, portions of the second storage material 112B, the capping layer material 114 and the top electrode material 116 not covered by the photoresist pattern PR1 are removed. In some embodiments, the photoresist pattern PR1 is removed after the patterning process by acceptable ashing process and/or photoresist stripping process. For example, in one embodiment, the photoresist pattern PR1 is removed using high pressure oxygen plasma, or the like. The disclosure is not limited thereto.

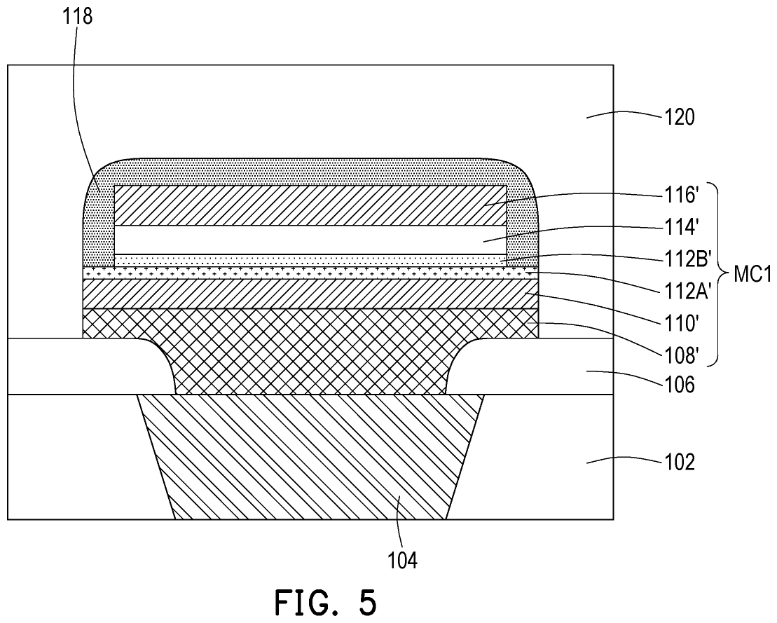

As illustrated in FIG. 5, after removing the photoresist pattern PR1, a spacer structure 118 may be formed on the second storage material 112B to laterally surround the second storage element layer 112B′, the capping layer 114′ and the top electrode 116′, and to cover a top surface of the top electrode 116′. The spacer structure 118 may include materials such as silicon nitride, silicon oxide, silicon oxynitride, some other dielectric, or a combination thereof, and may be formed by suitable deposition techniques such as CVD, PVD, ALD, or the like. In some embodiments, a second patterning process is performed to remove portions of the barrier layer 108, the bottom electrode material 110 and the first storage material 112A to form a patterned barrier layer 108′, a bottom electrode 110′ disposed on the barrier layer 108′, and a first storage element layer 112A′ disposed on the bottom electrode 110′.

In some embodiments, after the second patterning process, the formation of the memory cell MC1 is accomplished. In the exemplary embodiment, sidewalls of the spacer structure 118, sidewalls of the first storage element layer 112A′, sidewalls of the bottom electrode 110′ and sidewalls of the barrier layer 108′ may be substantially aligned with one another. In certain embodiments, sidewalls of the second storage element layer 112B′ are retracted from sidewalls of the first storage element layer 112A′. Similarly, sidewalls of the capping layer 114′ and sidewalls of the top electrode 116′ are also retracted from sidewalls of the first storage element layer 112A′.

After patterning to form the memory cell MC1, a dielectric layer 120 is formed on the dielectric layer 106 to cover and surround the memory cell MC1. For example, the dielectric layer 120 covers and contacts the sidewalls of the barrier layer 108′, the bottom electrode 110′ and the first storage element layer 112A′, and covers and contact the spacer structure 118. In some embodiments, the dielectric layer 120 may be an inter-level dielectric (ILD) layer, and may include one or more layers of an oxide, a low-κ dielectric, or an extra low-κ dielectric.

Referring to FIG. 6, after forming the dielectric layer 120, the spacer structure 118 and the dielectric layer 120 are patterned to form an opening revealing the top electrode 116′. Thereafter, a top via 122 is formed in the opening so that the top via 122 is electrically connected to the top electrode 116′. In some embodiments, the top via 122 may be formed of materials such as, copper (Cu), aluminum copper (AlCu), aluminum (Al), tungsten (W), or some other conductive material, and may be formed using CVD, ALD, PVD, or the like. After forming the top via 122, a memory structure 100A according to some embodiments of the present disclosure is accomplished.

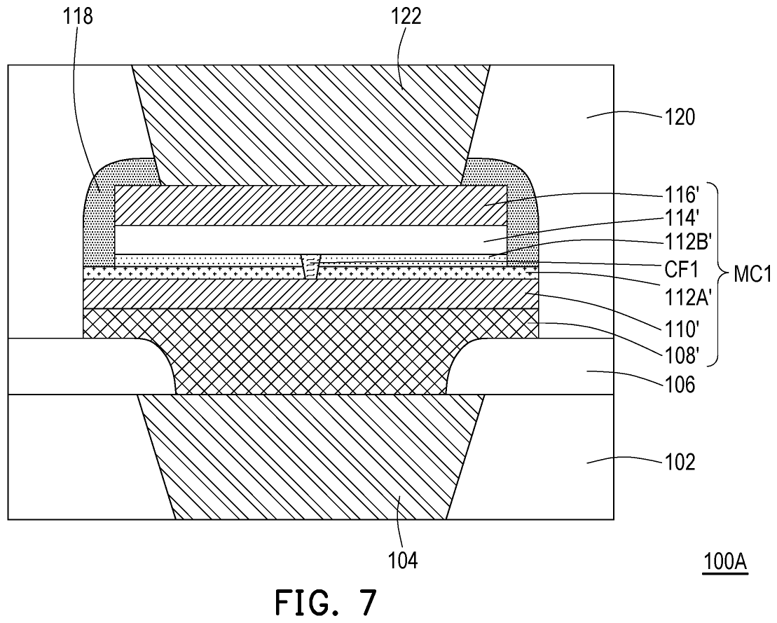

FIG. 7 is a schematic sectional view of a memory structure during operation in accordance with some embodiments of the present disclosure. Referring to FIG. 7, in the memory structure 100A, the first storage element layer 112A′ and the second storage element layer 112B′ of the memory cell MC1 are normally insulating. However, during an operation of the memory structure 100A, the first storage element layer 112A′ and the second storage element layer 112B′ can be made to conduct through a conductive filament CF1 formed by application of an appropriate voltage across the memory cell MC1. Although only one conductive filament CF1 is illustrated, it is noted that a plurality of conductive filaments CF1 may in fact be formed. Once the conductive filaments CF1 are formed, the conductive filaments CF1 may be reset (e.g., broken, resulting in a high resistance) or set (e.g., re-formed, resulting in a lower resistance) by application of an appropriate voltage across the memory cell MC1. The low and high resistances may be used to indicate a digital signal (i.e., “1” or “0”), thereby allowing for data storage.

In the exemplary embodiment, during operation of the memory structure 100A, the conductive filaments CF1 may have a relative high temperature concentrated at a bottom portion of the conductive filaments CF1. Since the bottom portion of the conductive filaments CF1 is surrounded by the first storage element layer 112A′ having a relatively high crystallization temperature, the high temperature or heat generated by the conductive filaments CF1 is less likely to cause crystallization and cause degradation of the first storage element layer 112A′. As such, a stability and reliability of the memory cell MC1 may be improved.

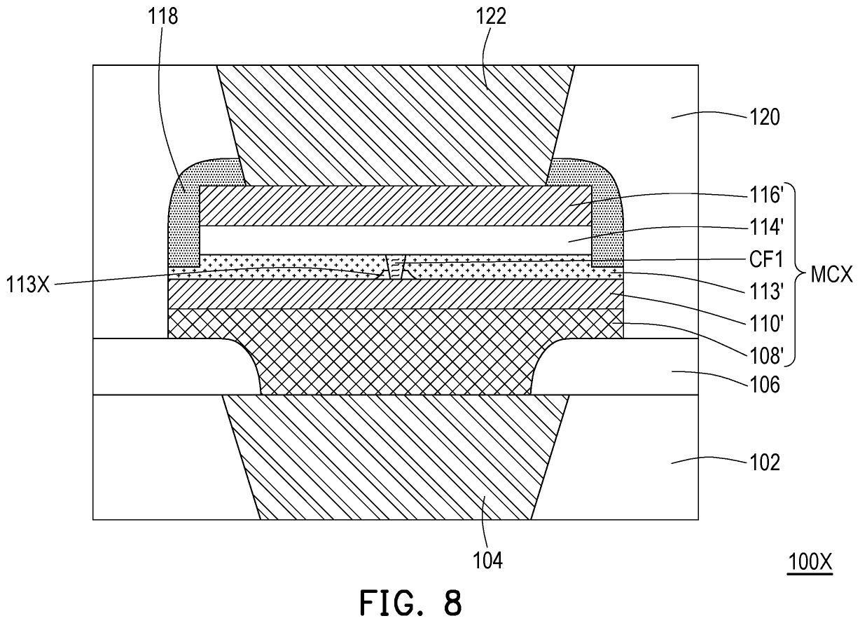

FIG. 8 is a schematic sectional view of a memory structure during operation in accordance with some comparative embodiments of the present disclosure. The memory structure 100X illustrated in FIG. 8 is similar to the memory structure 100A illustrated in FIG. 6 and FIG. 7. Therefore, the same reference numerals are used to refer to the same or liked parts, and its detailed description will be omitted herein. The difference between the embodiments is that a single storage element layer 113 is used to replace the first storage element layer 112A′ and the second storage element layer 112B′ in the memory structure 100X of FIG. 8. For example, the single storage element layer 113 is same as a material used in the second storage element layer 112B′.

In the comparative embodiment shown in FIG. 8, during operation of the memory structure 100X, as the storage element layer 113 has a relatively low crystallization temperature, it is likely that crystallized portions 113X of the storage element layer 113 will be formed due to a relative high temperature concentrated at a bottom portion of the conductive filaments CF1. As such, the formation of the crystallized portions 113X will cause the memory cell MCX to become unstable, and the memory cell MCX may easily degrade.

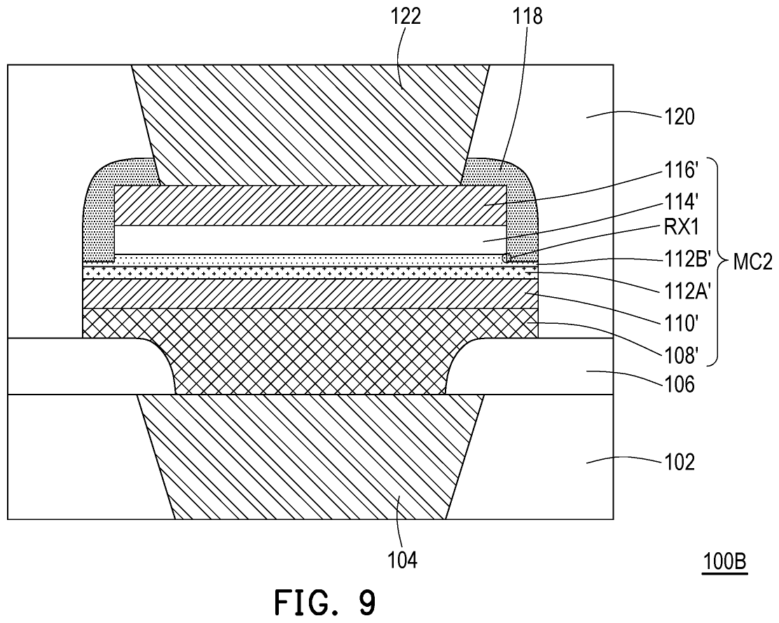

FIG. 9 is a schematic sectional view of a memory structure in accordance with some other embodiments of the present disclosure. The memory structure 110B illustrated in FIG. 9 is similar to the memory structure 100A illustrated in FIG. 6. Therefore, the same reference numerals are used to refer to the same or liked parts, and its detailed description will be omitted herein. The difference between the embodiments is that the memory cell MC2 shown in FIG. 9 is used in replacement of the memory cell MC1 shown in FIG. 6.

Referring to FIG. 6, in the memory cell MC1, the spacer structure 118 is formed so directly contact the first storage element layer 112A′. In other words, the second storage element layer 112B′ is etched to form retracted sidewalls. However, the disclosure is not limited thereto. As illustrated in FIG. 9, by controlling the etching steps, the second storage element layer 112B′ may be partially etched to form a retracted portion RX1. For example, sidewalls of the retracted portion RX1 of the second storage element layer 112B′ are aligned with sidewalls of the capping layer 114′ and sidewalls of the top electrode 116′. Furthermore, the sidewalls of the protruding part of the second storage element layer 112B′ may be aligned with sidewalls of the first storage element layer 112A′, the bottom electrode 110′ and the barrier layer 108′, while the spacer structure 118 may be disposed on the protruding part of the second storage element layer 112B′.

In the memory structure 110B illustrated in FIG. 9, during operation of the memory cell MC2, a bottom portion of the formed conductive filaments (not shown) will be surrounded by the first storage element layer 112A′ having a relatively high crystallization temperature. As such, the high temperature or heat generated by the conductive filaments is less likely to cause crystallization and cause degradation of the first storage element layer 112A′. Overall, a stability and reliability of the memory cell MC2 may be improved.

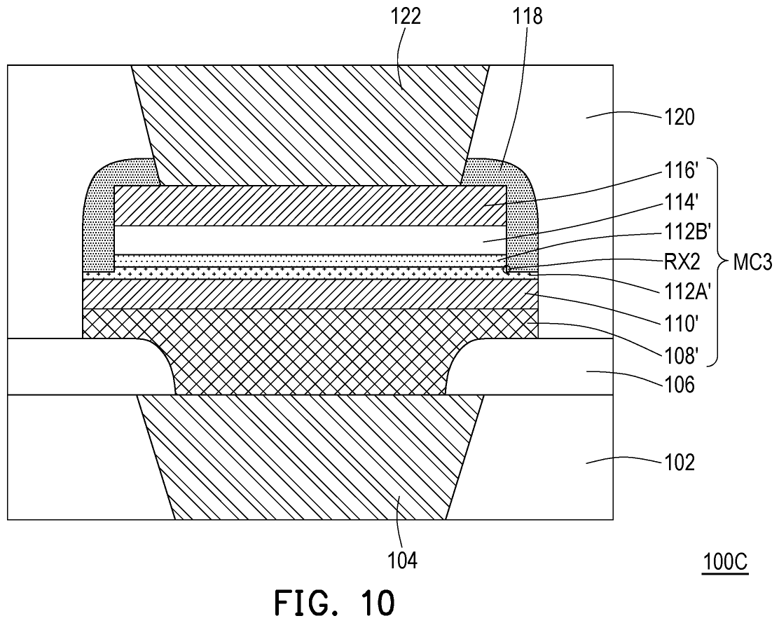

FIG. 10 is a schematic sectional view of a memory structure in accordance with some other embodiments of the present disclosure. The memory structure 110C illustrated in FIG. 10 is similar to the memory structure 100A illustrated in FIG. 6. Therefore, the same reference numerals are used to refer to the same or liked parts, and its detailed description will be omitted herein. The difference between the embodiments is that the memory cell MC3 shown in FIG. 10 is used in replacement of the memory cell MC1 shown in FIG. 6.

As illustrated in FIG. 10, in some embodiments, by controlling the etching steps, the second storage element layer 112B′ is etched to form retracted sidewalls, while the first storage element layer 112A′ is partially etched to form a retracted portion RX2. For example, sidewalls of the retracted portion RX2 of the first storage element layer 112A′ are aligned with sidewalls of the second storage element layer 112B′, sidewalls of the capping layer 114′ and sidewalls of the top electrode 116′. Furthermore, the sidewalls of the protruding part of the first storage element layer 112A′ may be aligned with sidewalls of the bottom electrode 110′ and the barrier layer 108′, while the spacer structure 118 may be disposed on the protruding part of the first storage element layer 112A′.

In the memory structure 110C illustrated in FIG. 10, during operation of the memory cell MC3, a bottom portion of the formed conductive filaments (not shown) will be surrounded by the first storage element layer 112A′ having a relatively high crystallization temperature. As such, the high temperature or heat generated by the conductive filaments is less likely to cause crystallization and cause degradation of the first storage element layer 112A′. Overall, a stability and reliability of the memory cell MC3 may be improved.

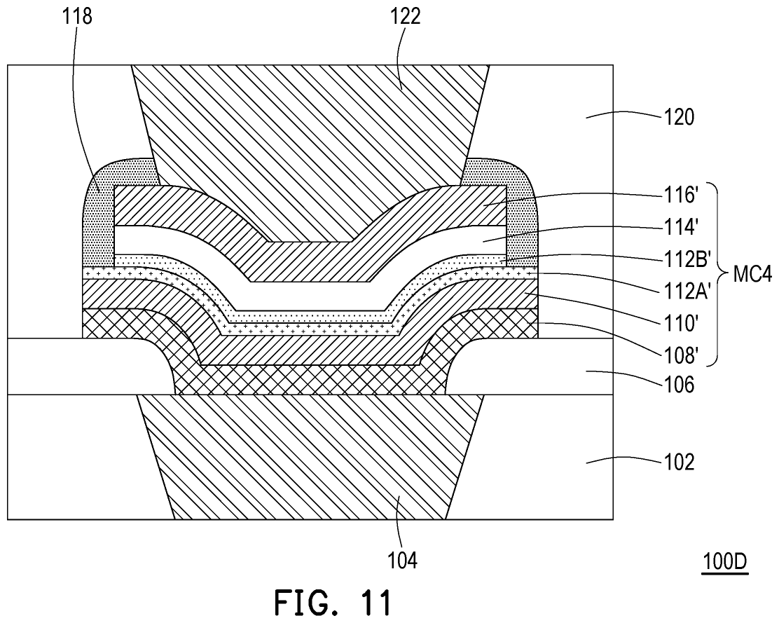

FIG. 11 is a schematic sectional view of a memory structure in accordance with some other embodiments of the present disclosure. The memory structure 110D illustrated in FIG. 11 is similar to the memory structure 100A illustrated in FIG. 6. Therefore, the same reference numerals are used to refer to the same or liked parts, and its detailed description will be omitted herein. The difference between the embodiments is that the memory cell MC4 shown in FIG. 11 is used in replacement of the memory cell MC1 shown in FIG. 6.

Referring to FIG. 6, the memory cell MC1 is a planar cell, whereby the barrier layer 108′, the bottom electrode 110′, the first storage element layer 112A′, the second storage element layer 112B′, the capping layer 114′ and the top electrode 116′ are formed to have planar top surfaces. However, the disclosure is not limited thereto. Referring to FIG. 11, in the exemplary embodiment, the memory cell MC4 is a non-planar cell, whereby the barrier layer 108′, the bottom electrode 110′, the first storage element layer 112A′, the second storage element layer 112B′, the capping layer 114′ and the top electrode 116′ are formed to have are formed to have non-planar top surfaces. For example, in some embodiments, the barrier layer 108′ is conformally formed in the openings of the dielectric layer 106, whereas the bottom electrode 110′, the first storage element layer 112A′, the second storage element layer 112B′, the capping layer 114′ and the top electrode 116′ are sequentially and conformally formed over the barrier layer 108′. In other words, in the memory structure 100D, the barrier layer 108′, the bottom electrode 110′, the first storage element layer 112A′, the second storage element layer 112B′, the capping layer 114′ and the top electrode 116′ may respectively include a depressed portion. Furthermore, in the exemplary embodiment, the top via 122 is formed with a protruding portion that is in contact with a top surface of the depressed portion of the top electrode 116′.

Similar to the above embodiments, in the memory structure 110D illustrated in FIG. 11, during operation of the memory cell MC4, a bottom portion of the formed conductive filaments (not shown) will be surrounded by the first storage element layer 112A′ having a relatively high crystallization temperature. As such, the high temperature or heat generated by the conductive filaments is less likely to cause crystallization and cause degradation of the first storage element layer 112A′. Overall, a stability and reliability of the memory cell MC4 may be improved.

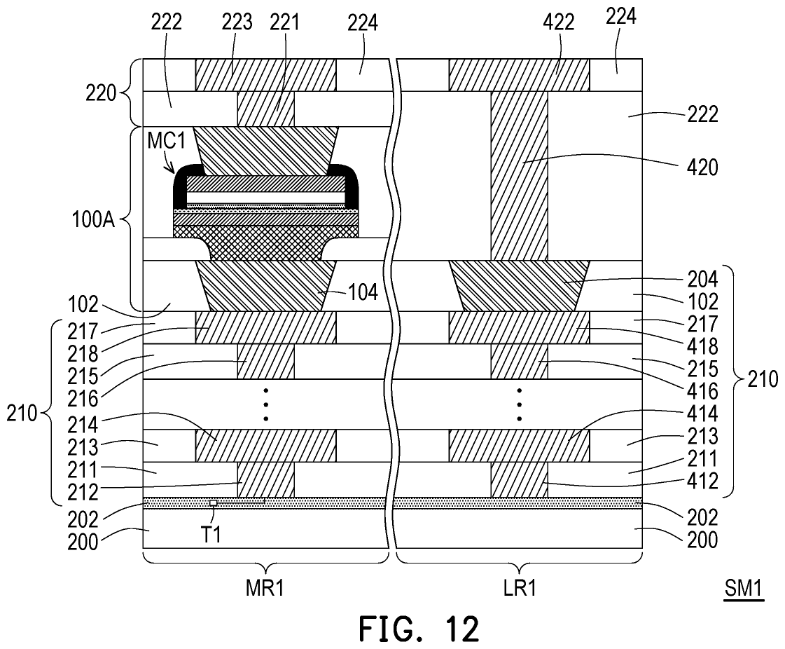

FIG. 12 is a schematic sectional view of a semiconductor device in accordance with some embodiments of the present disclosure. The memory cell MC1 illustrated in the embodiment of FIG. 12 is applied to, but not limited thereto, a RRAM cell. The structures, materials, and processes may be similar to what are shown in, and discussed referring to, FIG. 1 through FIG. 6. The details are thus no repeated herein. It is noted that other memory cells MC2, MC3, and MC4 of the memory structures 100B, 100C, 100D may individually substitute the memory cell MC1 of the memory structure 100A shown in FIG. 12 to form the semiconductor device of the example.

Referring to FIG. 12, a semiconductor device SM1 may include memory region MR1 and a logic region LR1. In some embodiments, the memory region MR1 includes a substrate 200, a device region 202, a first interconnect structure 210, the memory structure 100A illustrated in FIG. 6, and a second interconnect structure 220. In certain embodiments, the logic region LR includes the substrate 200, the device region 202, the first interconnect structure 210, the electrode layer 204 and the second interconnect structure 220.

In some embodiments, the substrate 200 is a semiconductor substrate, such as a bulk semiconductor, a semiconductor-on-insulator (SOI) substrate, or the like. The substrate 200 may be doped (e.g., with a p-type or an n-type dopant) or undoped. The substrate 200 may be a wafer, such as a silicon wafer. Generally, the SOI substrate is a layer of a semiconductor material formed on an insulator layer. The insulator layer is, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the substrate 200 includes an element semiconductor such as silicon or germanium, a compound semiconductor such as silicon carbide, gallium arsenic, gallium phosphide, indium phosphide, indium arsenide and indium antimonide, an alloy semiconductor such as SiGe, GaAsP, AlInAs, AlGaAs, GaInAs, GaInP and GaInAsP or combinations thereof.

In some embodiments, the device region 202 is disposed on the substrate 200 in a front-end-of-line (FEOL) process. The device region 202 may include a wide variety of devices. In some embodiments, the devices include active components, passive components, or a combination thereof. In some other embodiments, the devices include integrated circuits devices. The devices are, for example, transistors, capacitors, resistors, diodes, photodiodes, fuse devices, or other similar devices. In an embodiment, the device region 202 includes a gate structure, source and drain regions, and isolation structures such as shallow trench isolation (STI) structures (not shown). In the device region 202, various N-type metal-oxide semiconductor (NMOS) and/or P-type metal-oxide semiconductor (PMOS) devices, such as transistors or memories and the like, may be formed and interconnected to perform one or more functions. In the exemplary embodiment, at least one transistor T1 in the device region 202 is electrically connected to the memory cell MC1 of the memory structure 100A to form a 1T1R (1 transistor, 1 RRAM) structure. Furthermore, other devices, such as capacitors, resistors, diodes, photodiodes, fuses and the like may also be formed over the substrate 200. The functions of the devices may include memory, processors, sensors, amplifiers, power distribution, input/output circuitry, or the like.

As illustrated in FIG. 12, the first interconnect structure 210 in the memory region MR1 is disposed on the device region 202, and the device region 202 is disposed between the substrate 200 and the first interconnect structure 210. In some embodiments, the first interconnect structure 210 includes a plurality of build-up layers (M1 to Mx−1, where x is a positive integer of 3 or greater; not labeled) formed with insulating layers and conductive layers. For example, the first interconnect structure 210 at least includes insulating layers 211, 213, 215, 217, conductive vias 212, 216, and conductive layers 214, 218. The conductive via 212 is disposed on and electrically connected to the device region 202. The conductive layer 214 is disposed on and electrically connected to the conductive via 212. The insulating layers 211, 213 are collectively referred to as an inter-metal dielectric (IMD) layer laterally wrapping the conductive via 212 and the conductive layer 214 to constitute a build-up layer M1. On the other hand, the conductive layer 218 is disposed on and electrically connected to the conductive via 216. The insulating layers 215, 217 are collectively referred to as an IMD layer laterally wrapping the conductive via 216 and the conductive layer 218 to constitute another build-up layer Mx−1. As shown in FIG. 12, the build-up layer M1 (211, 212, 213 214) is electrically connected to the build-up layer Mx−1 (215, 216, 217, 218) through other build-up layer(s) (not shown), for example. Alternatively, the build-up layer M1 (211, 212, 213 214) may be electrically connected to the build-up layer Mx−1 (215, 216, 217, 218) directly.

In a similar way, the first interconnect structure 210 in the logic region LR1 is disposed on the device region 202, and the device region 202 is disposed between the substrate 200 and the first interconnect structure 210. In some embodiments, the first interconnect structure 210 is electrically connected to the logic devices in the device region 202. In some embodiments, the first interconnect structure 210 in the logic region includes a plurality of build-up layers (M1′ to Mn−1, where n is a positive integer of 3 or greater; not labeled) formed with insulating layers and conductive layers. For example, the first interconnect structure 210 in the logic region LR1 at least includes insulating layers 211, 213, 215, 217, conductive vias 412, 416, and conductive layers 414, 418. The conductive via 412 is disposed on and electrically connected to the device region 202. The conductive layer 414 is disposed on and electrically connected to the conductive via 412. The insulating layers 211, 213 are laterally wrapping the conductive via 412 and the conductive layer 414 to constitute a build-up layer M1′. On the other hand, the conductive layer 418 is disposed on and electrically connected to the conductive via 416. The insulating layers 215, 217 are laterally wrapping the conductive via 416 and the conductive layer 418 to constitute another build-up layer Mn−1. As shown in FIG. 12, the build-up layer M1′ (211, 213, 412, 414) is electrically connected to the build-up layer Mn−1 (215, 217, 416, 418) through other build-up layer(s) (not shown), for example. Alternatively, the build-up layer M1′ (211, 213, 412, 414) may be electrically connected to the build-up layer Mn−1 (215, 217, 416, 418) directly.

As further illustrated in FIG. 12, the memory structure 100A and the second interconnect structure 220 are sequentially stacked on the first interconnect structure 210 in the memory region MR1. For example, the memory structure 100A is electrically connecting the first interconnect structure 210 to the second interconnect structure 220. In some embodiments, the bottom via 104 of the memory structure MC1 is in contact and electrically connected to the conductive layer 218 of the first interconnect structure 210, and the top via 122 of the memory cell MC1 is in contact and electrically connected to the second interconnect structure 220. In some embodiments, the second interconnect structure 220 in the memory region MR may include insulating layers 222, 224, conductive via 221 and conductive layer 223. The conductive via 221 is disposed on and electrically connected to the memory cell MC1. The conductive layer 223 is disposed on and electrically connected to the conductive via 221. The insulating layers 222, 224 are laterally wrapping the conductive via 221 and the conductive layer 223 to constitute a build-up layer (not labelled) or a part of a build-up layer. In some other embodiments, one of the memory cells MC2, MC3, or MC4 are used to replace the memory cell MC1.

Furthermore, in some embodiments, the electrode layer 204 and the second interconnect structure 220 are sequentially stacked on the first interconnect structure 120 in the logic region LR1. The electrode layer 204 is electrically connected to the first interconnect structure 210 and the second interconnect structure 220. The second interconnect structure 210 in the logic region LR1 may include insulating layers 222, 224, conductive via 420 and conductive layer 422. The conductive via 420 is disposed on and electrically connected to the electrode layer 204. The conductive layer 422 is disposed on and electrically connected to the conductive via 420. The insulating layers 222, 224 are laterally wrapping the conductive via 420 and the conductive layer 422 to constitute a build-up layer (not labelled) or a part of a build-up layer.

In some embodiments, the insulating layers 211, 213, 215, 217, 222 and 224 are independently made of a dielectric material, such as silicon oxide, silicon nitride, silicon oxynitride, a spin-on dielectric material, or a low-k dielectric material. The conductive layers 214, 218, 414, 418, 223, 422 each may be a conductive trace/line/wire. The conductive layers 214, 218, 414, 418, 223, 422 and the conductive vias 212, 216, 221, 412, 416, 420 may independently include metals or metal alloys including one or more of Al, AlCu, Cu, Ti, TiN, W, or the like. The conductive layers 214, 218, 223 may be a portion of a current driving circuit (not shown) to provide voltages to the memory cell MC1. In some embodiments, the conductive vias 212, 216, 221, 412, 416, 420 and the conductive layers 214, 218, 414, 418, 223, 422 are formed by a dual damascene process. That is, the conductive vias 212, 216, 221, 412, 416, 420 and the conductive layers 214, 218, 414, 418, 223, 422 may be formed simultaneously. In some embodiments, the memory structure 100A may be disposed between any two adjacent conductive layers in the back-end-of-line (BEOL) structure. In certain embodiments, the fabricating process of the memory structure 100A (with memory cell MC1) may be compatible with the BEOL process of the semiconductor device, thereby simplifying process steps and efficiently improving the integration density.

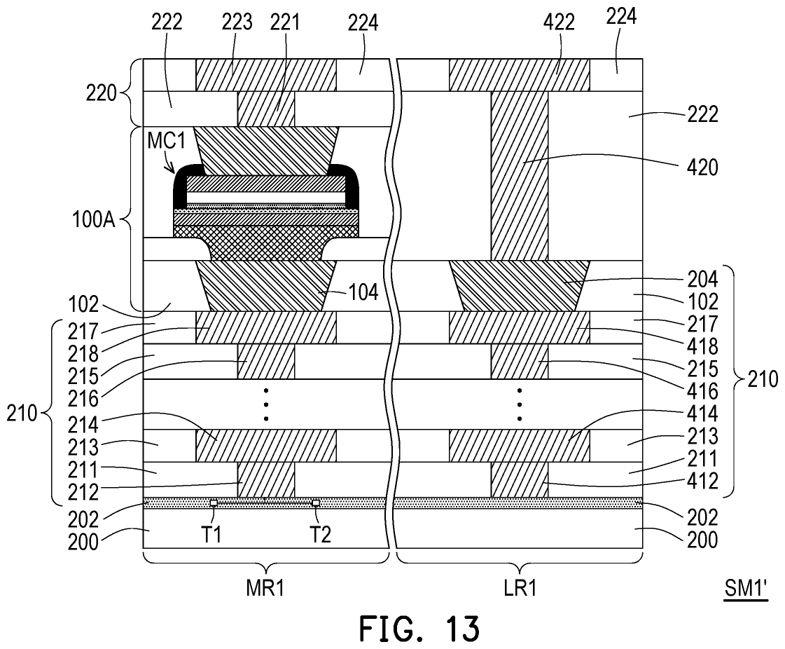

FIG. 13 is a schematic sectional view of a semiconductor device in accordance with some other embodiments of the present disclosure. The semiconductor device SM1′ illustrated in FIG. 13 is similar to the semiconductor device SM1 illustrated in FIG. 12. Therefore, the same reference numerals are used to refer to the same or liked parts, and its detailed description will be omitted herein. The difference between the embodiments is that in the device region 202 of FIG. 13, a first transistor T1 and a second transistor T2 in the device region 202 are electrically connected to the memory cell MC1 of the memory structure 100A to form a 2T1R (2 transistor, 1 RRAM) structure.

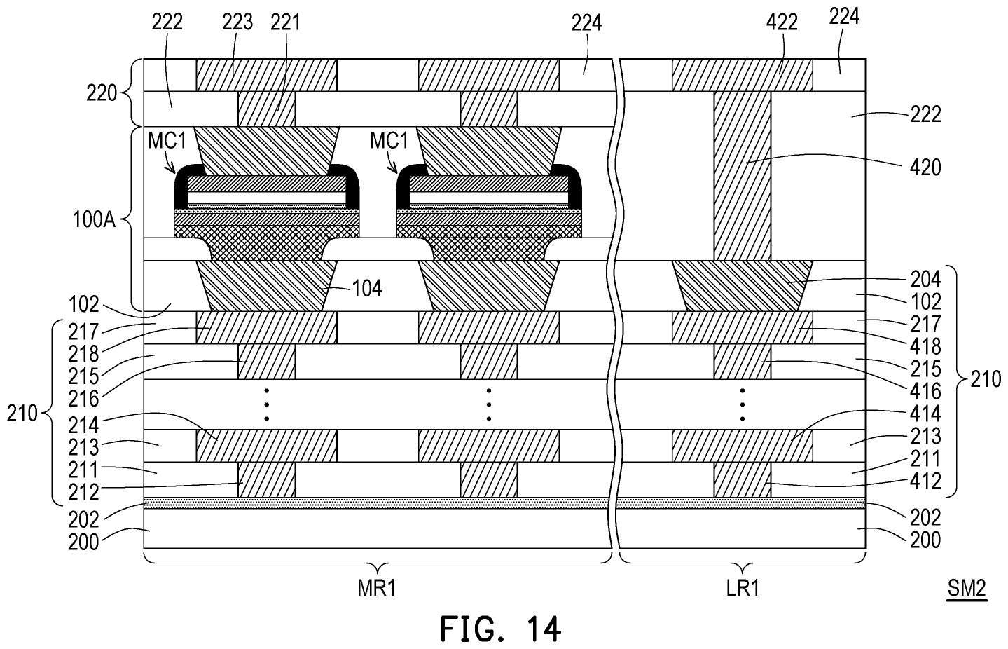

FIG. 14 is a schematic sectional view of a semiconductor device in accordance with some other embodiments of the present disclosure. The semiconductor device SM2 illustrated in FIG. 14 is similar to the semiconductor device SM1 illustrated in FIG. 12. Therefore, the same reference numerals are used to refer to the same or liked parts, and its detailed description will be omitted herein. The difference between the embodiments is that a plurality of memory cells MC1 is illustrated in the semiconductor device SM2 of FIG. 14. For example, as illustrated in FIG. 14, the memory structure 100A includes two memory cells MC1 located in between the first interconnection structure 210 and the second interconnection structure 220 in the memory region MR1. In some embodiments, the two memory cells MC1 may be electrically coupled to one another through the first interconnection structure 210. The two memory cells MC1 may correspond to the memory cell MC1 illustrated in FIG. 6, thus its detailed description will be omitted herein.

Although two identical memory cells MC1 are illustrated herein, it is appreciated that two identical memory cells (e.g. MC1, MC2, MC3, or MC4) or two different memory cells (e.g. MC1, MC2, MC3, and MC4) may be included in the semiconductor device. For example, a semiconductor device may include a memory cell MC1 and a memory cell MC2; the semiconductor device may include a memory cell MC1 and a memory cell MC3; the semiconductor device may include a memory cell MC1 and a memory cell MC4; the semiconductor device may include a memory cell MC2 and a memory cell MC3; the semiconductor device may include a memory cell MC2 and a memory cell MC4; the semiconductor device may include a memory cell MC3 and a memory cell MC4.

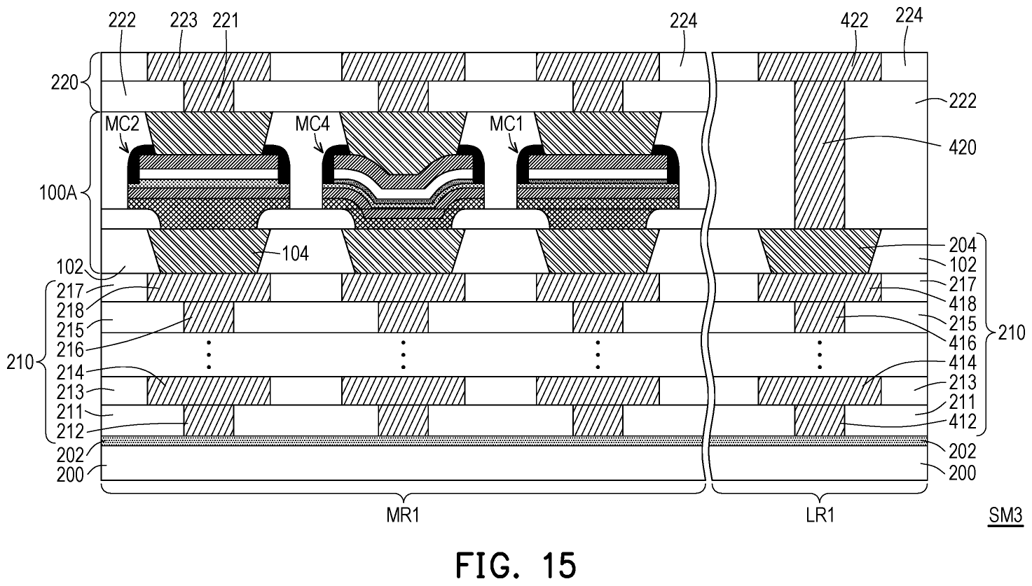

FIG. 15 is a schematic sectional view of a semiconductor device in accordance with some other embodiments of the present disclosure. The semiconductor device SM3 illustrated in FIG. 15 is similar to the semiconductor device SM1 illustrated in FIG. 12. Therefore, the same reference numerals are used to refer to the same or liked parts, and its detailed description will be omitted herein. In the above embodiments, although one or two memory cells MC1 are illustrated in the memory region MR1, it is appreciated that the number of memory cells (MC1, MC2, MC3, and MC4) located in the memory region MR1 of the semiconductor device is not limited to one or two, but can be three or more.

For example, as illustrated in FIG. 15, in some embodiments, the memory region MR1 includes at least the memory cell MC1 illustrated in FIG. 6, the memory cell MC2 illustrated in FIG. 9, and the memory cell MC4 illustrated in FIG. 11. From the above embodiment, it is appreciated that in case where a plurality of memory cells (MC1, MC2, MC3, and MC4) exist in the semiconductor device, the memory cells (MC1, MC2, MC3, and MC4) may be used alone (all the same type of memory cells), or be used in combination (different types of memory cells). Furthermore, the number of memory cells (MC1, MC2, MC3, and MC4) located in the memory region MR1 may be adjusted based on product requirement.

In the above-mentioned embodiments, the memory structure includes a first storage element layer and a second storage element layer sandwiched between a bottom electrode and a top electrode to form a memory cell, whereby a crystallization temperature of the first storage element layer is higher than a crystallization temperature of the second storage element layer. As such, during operation of the memory structure, since a bottom portion of the formed conductive filaments is surrounded by the first storage element layer having a relatively high crystallization temperature, the high temperature or heat generated by the conductive filaments is less likely to cause crystallization and cause degradation of the first storage element layer. Overall, a stability and reliability of the memory cell in the memory structure may be improved.

In accordance with some embodiments of the present disclosure, a memory structure includes a bottom via, a memory cell and a top via. The memory cell is disposed on the bottom via and includes a bottom electrode, a top electrode and a first storage element layer and a second storage element layer sandwiched between the bottom electrode and the top electrode. The first storage element layer is in contact with the bottom electrode, and a crystallization temperature of the first storage element layer is higher than a crystallization temperature of the second storage element layer. The top via is disposed on the memory cell and electrically connected to the top electrode.

In accordance with some other embodiments of the present disclosure, a semiconductor device includes a device region, a first interconnect structure, a memory structure, and a second interconnect structure. The device region is disposed on a substrate. The first interconnect structure is connected to the device region, and located on the substrate. The memory structure is disposed on the first interconnect structure, and includes a bottom via, a memory cell, and a top via. The bottom via is connected to the first interconnect structure. The memory cell is disposed on the bottom via and includes a bottom electrode, a first storage element layer, a second storage element layer, a capping layer and a top electrode stacked up in sequence over the bottom via. The first storage element layer includes a combination of a first material having a bandgap of 5 eV or less, and at least one second material having a bandgap of 6 eV or more, and the second storage element layer includes a material different than that of the first storage element layer. The top via is disposed on the memory cell and electrically connected to the top electrode. The second interconnect structure is disposed on the memory structure and electrically connected to the top via.

In accordance with yet another embodiment of the present disclosure, a method of fabricating a memory structure is described. The method includes the following steps. A bottom via is formed. A memory cell is formed on the bottom via. Forming the memory cell includes the following steps/A bottom electrode is formed. A first storage element layer and a second storage element layer are formed on the bottom electrode, wherein a crystallization temperature of the first storage element layer is higher than a crystallization temperature of the second storage element layer. A top electrode is formed on the second storage element layer, wherein the first storage element layer and the second storage element layer are sandwiched between the bottom electrode and the top electrode, and wherein the first storage element layer is in contact with the bottom electrode. A top via is formed on the memory cell, and the top via is electrically connected to the top electrode.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A memory structure, comprising:
a bottom via;
a memory cell disposed on the bottom via, and comprising:
a bottom electrode;
a top electrode; and
a first storage element layer and a second storage element layer sandwiched between the bottom electrode and the top electrode, wherein the first storage element layer is in contact with the bottom electrode, and wherein a crystallization temperature of the first storage element layer is higher than a crystallization temperature of the second storage element layer; and
a top via disposed on the memory cell and electrically connected to the top electrode.

2. The structure according to claim 1, wherein the first storage element layer comprises a combination of tantalum oxide and aluminum oxide, or a combination of tantalum oxide and silicon oxide.

3. The structure according to claim 2, wherein when the first storage element layer comprises the combination of tantalum oxide and aluminum oxide, an atomic profile of aluminum is higher at a bottom surface of the first storage element layer than at a top surface of the first storage element layer, and when the first storage element layer comprises the combination of tantalum oxide and silicon oxide, an atomic profile of silicon is higher at the bottom surface of the first storage element layer than at the top surface of the first storage element layer.

4. The structure according to claim 1, wherein the second storage element layer is a material selected from the group consisting of zirconium tantalum oxide (ZrTaO), hafnium tantalum oxide (HfTaO), hafnium aluminum oxide (HfAlO), hafnium oxide (HfO₂), and zirconium oxide (ZrO₂).

5. The memory structure according to claim 1, wherein the memory cell further comprises:
a capping layer located in between the second storage element layer and the top electrode; and
a barrier layer located in between the bottom electrode and the bottom via.

6. The memory structure according to claim 5, further comprising a spacer structure laterally surrounding the second storage element layer, the capping layer and the top electrode.

7. The memory structure according to claim 1, wherein sidewalls of the second storage element layer are retracted from sidewalls of the first storage element layer.

8. A semiconductor device, comprising:
a device region disposed on a substrate;
a first interconnect structure connected to the device region, and located on the substrate;
a memory structure disposed on the first interconnect structure, wherein the memory structure comprises:
a bottom via connected to the first interconnect structure;
a memory cell disposed on the bottom via and comprising a bottom electrode, a first storage element layer, a second storage element layer, a capping layer and a top electrode stacked up in sequence over the bottom via, wherein the first storage element layer comprises a combination of a first material having a bandgap of 5 eV or less, and at least one second material having a bandgap of 6 eV or more, and the second storage element layer comprises a material different than that of the first storage element layer; and
a top via disposed on the memory cell and electrically connected to the top electrode; and
a second interconnect structure disposed on the memory structure and electrically connected to the top via.

9. The semiconductor device according to claim 8, wherein the first material of the first storage element layer is tantalum oxide, and the at least one second material of the first storage element layer is aluminum oxide, silicon oxide, or a combination of aluminum oxide and silicon oxide.

10. The semiconductor device according to claim 8, wherein a sum of a thickness of the first storage element layer and a thickness of the second storage element layer is in a range of 10 angstroms to 100 angstroms.

11. The semiconductor device according to claim 8, wherein the second storage element layer comprises a retracted portion, and sidewalls of the retracted portion are aligned with sidewalls of the capping layer and sidewalls of the top electrode.

12. The semiconductor device according to claim 8, wherein a crystallization temperature of the first storage element layer is higher than a crystallization temperature of the second storage element layer.

13. The semiconductor device according to claim 8, wherein the first material and the second material are evenly distributed in the first storage element layer to have a uniform atomic profile of elements from a bottom surface to a top surface of the first storage element layer.

14. The semiconductor device according to claim 8, wherein the memory structure further comprises a spacer structure disposed on the first storage element layer and laterally surrounding the second storage element layer, the capping layer and the top electrode.

15. A method of fabricating a memory structure, comprising:
forming a bottom via;
forming a memory cell on the bottom via, wherein forming the memory cell comprises:
forming a bottom electrode;
forming a first storage element layer and a second storage element layer on the bottom electrode, wherein a crystallization temperature of the first storage element layer is higher than a crystallization temperature of the second storage element layer;
forming a top electrode on the second storage element layer, wherein the first storage element layer and the second storage element layer are sandwiched between the bottom electrode and the top electrode, and wherein the first storage element layer is in contact with the bottom electrode; and
forming a top via on the memory cell, and electrically connecting the top via to the top electrode.

16. The method according to claim 15, wherein the first storage element layer is formed with a combination of tantalum oxide and aluminum oxide, or formed with a combination of tantalum oxide and silicon oxide.

17. The method according to claim 15, wherein the second storage element layer is formed with a material selected from the group consisting of zirconium tantalum oxide (ZrTaO), hafnium tantalum oxide (HfTaO), hafnium aluminum oxide (HfAlO), hafnium oxide (HfO₂), and zirconium oxide (ZrO₂).

18. The method according to claim 15, wherein forming the memory cell further comprises:
forming a barrier layer on the bottom via prior to forming the bottom electrode;
forming the bottom electrode on the barrier layer;
forming a capping layer on the second storage element layer prior to forming the top electrode; and
forming the top electrode on the capping layer.

19. The method according to claim 18, wherein forming the memory cell further comprises forming a spacer structure laterally surrounding the second storage element layer, the capping layer and the top electrode.

20. The method according to claim 15, wherein forming the first storage element layer and the second storage element layer comprises:
forming a first storage material on the bottom electrode;
forming a second storage material on the first storage material;
patterning the second storage material to form the second storage element layer having retracted sidewalls; and
patterning the first storage material to form the first storage element layer.
